(19) United States
(12) Patent Application Publication
(10) Pub. No.: US 2015/0309411 A1
(43) Pub. Date: Oct. 29, 2015

(54) Methods of Forming Pattern by Using Dual Tone Development Processes

(71) Applicant: Samsung Electronics Co., Ltd., Suwon-si (KR)

(72) Inventors: Sung-wook HWANG, Seongnam-si (KR); Soon-mok HA, Hwaseong-si (KR); Joon-soo PARK, Seongnam-si (KR)

(21) Appl. No.: 14/679,054

(22) Filed: Apr. 6, 2015

(30) Foreign Application Priority Data
Apr. 23, 2014 (KR) 10-2014-0048876

(51) Int. Cl. G03F 7/20

(52) U.S. Cl. CPC G03F 7/20

(57) ABSTRACT

Methods of forming a pattern are provided. The methods may include forming a dual tone photoresist layer on a support layer, forming a low light exposure region, a middle light exposure region, and a high light exposure region in a first region of the dual tone photoresist layer and forming a low light exposure region and a middle light exposure region in a second region of the dual tone photoresist layer by exposing the dual tone photoresist layer to light by using a mask comprising a gray feature. The method may also include forming preliminary patterns in the first region by performing a positive development process and forming first patterns which are spaced apart from one another in the first region and second patterns which are spaced apart from one another in the second region by performing a negative development process.

### CROSS-REFERENCE TO RELATED APPLICATION

This U.S. non-provisional patent application claims priority under 35U.S.C. §119 to Korean Patent Application No. 10-2014-0048876, filed on Apr. 23, 2014, in the Korean Intellectual Property Office, the disclosure of which is hereby incorporated by reference herein in its entirety.

### BACKGROUND

1. Technical Field

The inventive concept relates to a method of forming a pattern, and more particularly, to a method of forming a pattern by using a dual tone development process.

2. Discussion of Related Art

When semiconductor devices are manufactured, patterns are formed by a photolithography process. As semiconductor devices have become highly integrated, patterns having small pitches are needed. Also, patterns having large pitches, such as an insulating pattern, a test pattern, an overlay pattern, and an align pattern, may be needed. Thus, to manufacture semiconductor devices, patterns having smaller pitches than a mask pattern, patterns having pitches of different sizes, or bulk patterns of various shapes are needed.

### SUMMARY

A method of forming a pattern according to the present inventive concept may include forming patterns having smaller pitches than pitches of a mask pattern, patterns having pitches of different sizes, or bulk patterns of various shapes by using a dual tone development process.

A method of forming patterns according to some embodiments may include forming a dual tone photoresist layer on a support layer, forming a low light exposure region, a middle light exposure region and a high light exposure region in a first region of the dual tone photoresist layer and forming a low light exposure region and a middle light exposure region in a second region of the dual tone photoresist layer by exposing the dual tone photoresist layer to light by using a mask including a gray feature. The method may also include forming a plurality of preliminary patterns in the first region by removing the dual tone photoresist layer of the high light exposure region of the first region by performing a positive development process and forming a plurality of first patterns which are spaced apart from one another in the first region and a plurality of second patterns which are spaced apart from one another in the second region by removing the dual tone photoresist layer of the low light exposure region in the first region and the dual tone photoresist layer of the low light exposure region in the second region by performing a negative development process.

In various embodiments, the plurality of first patterns may have pitches smaller than pitches of the plurality of preliminary patterns. The plurality of second patterns may have pitches larger than pitches of the plurality of first patterns. The plurality of second patterns may be bulk patterns. The plurality of second patterns may be polygonal patterns or circular patterns.

According to various embodiments, the mask may include a plurality of mask patterns which are spaced apart from one another on a mask substrate, and the gray feature comprises a sub-resolution feature which is formed in the plurality of mask patterns which expose the second region to light. Sizes of the plurality of mask patterns may be the same as or smaller than sizes of the plurality of preliminary patterns and the plurality of second patterns.

In various embodiments, the mask may include a plurality of mask patterns which are spaced apart from one another on a mask substrate and the gray feature comprises a sub-resolution feature which is formed between the plurality of mask patterns which expose the second region to light.

In various embodiments, the mask may include a plurality of polygonal mask patterns which are spaced apart from one another on a mask substrate, and the plurality of second patterns comprise a plurality of polygonal patterns which are formed on the support layer and comprises round corners.

According to various embodiments, the mask may include a plurality of circular mask patterns which are spaced apart from one another on a mask substrate, and the plurality of second patterns comprise a plurality of circular patterns which are spaced apart from one another on the support layer and comprise round shapes.

A method of forming a pattern according to some embodiments of the present inventive concept, the method may include forming a dual tone photoresist layer on a support layer, forming a low light exposure region, a middle light exposure region and a high light exposure region in a first region of the dual tone photoresist layer, and forming a low light exposure region and a middle light exposure region in a second region of the dual tone photoresist layer, by exposing the dual tone photoresist layer to light by using a mask in which a plurality of mask patterns that are spaced apart from one another in the first mask region and the second mask region and a gray feature that is formed in the second mask region are arranged. The first region may correspond to a first mask region, and the second region may correspond to a second mask region. The method may also include forming a plurality of preliminary patterns in the first region by removing the dual tone photoresist layer in the high light exposure region of the first region by performing a positive development process and forming a plurality of first patterns which are spaced apart from one another in the middle light exposure region of the first region and a plurality of second patterns which are spaced apart from one another in the middle light exposure region of the second region, by removing the double tone photoresist layer of the low light exposure region of the plurality of preliminary patterns of the first region and the double tone photoresist layer in the low light exposure region of the second region by performing a negative development process.

According to various embodiments, the gray feature may be a sub-resolution feature which is formed in the plurality of mask patterns in the second mask region or between the plurality of mask patterns in the second mask region.

In various embodiments, widths of the plurality of first patterns may be a width of the middle light exposure region of the first region.

In various embodiments, widths of the plurality of second patterns may be a width of the middle light exposure region of the second region.

In various embodiments, a width of the middle light exposure region of the second region may be greater than a width of the middle light exposure region of the first region.

A method of forming a pattern according some embodiments of the present inventive concept may include forming a dual tone photoresist layer on a support layer, exposing the dual tone photoresist layer to light by using a mask comprising a gray feature, removing the dual tone photoresist layer in a first portion of a first region by performing a positive development process and removing the dual tone photoresist layer in a second portion of the first region and removing the dual tone photoresist layer in a first portion of a second region by performing a negative development process.

According to various embodiments, the first portion of the first region may be a high light exposure region, and the second portion of the first region comprises a low light exposure region.

In various embodiments, the first portion of the second region may be a low right exposure region.

In various embodiments, the gray feature may be a sub-resolution feature which is formed in a plurality of mask patterns of a second mask region or between the plurality of mask patterns of the second mask region.

According to various embodiments after forming the dual tone photoresist layer, a soft bake process may be performed.

### BRIEF DESCRIPTION OF THE DRAWINGS

Example embodiments of the inventive concept will be more clearly understood from the following detailed description taken in conjunction with the accompanying drawings.

FIG. 1 is a cross-sectional view for describing a method of forming a pattern by using a dual tone development process according to an example embodiment of the inventive concept.

FIGS. 2 and 3 are cross-sectional views for describing a method of forming a pattern by using a dual tone development process according to an example embodiment of the inventive concept.

FIG. 4 is a manufacturing process flowchart for describing the method of forming the pattern by using the dual tone development process described with reference to FIGS. 2 and 3.

FIGS. 5 and 6 are cross-sectional views for describing a method of forming a pattern by using a dual tone development process according to an example embodiment of the inventive concept.

FIGS. 7 and 9 are plan views of a first mask used in a method of forming a pattern according to an example embodiment and a comparative example embodiment of the inventive concept.

FIGS. 8 and 10 are plan views of a distribution of a light exposure intensity of a light exposure region when the light exposure is performed by using a first mask of FIGS. 7 and 9, respectively.

FIGS. 11 and 13 are plan views of a first mask used in a method of forming a pattern, according to an example embodiment and a comparative example embodiment of the inventive concept.

FIGS. 12 and 14 are plan views of a distribution of a light exposure intensity of a light exposure region when the light exposure is performed by using the first mask of FIGS. 11 and 13, respectively.

FIGS. 15 and 17 are plan views of a first mask used in a method of forming a pattern, according to an example embodiment and a comparative example embodiment of the inventive concept.

FIGS. 16 and 18 are plan views of a distribution of a light exposure intensity of a light exposure region when the light exposure is performed by using the first mask of FIGS. 15 and 17, respectively.

FIGS. 19 and 20 are cross-sectional views for describing a method of forming a pattern by using a dual tone development process according to an example embodiment of the inventive concept.

FIG. 21 is a manufacturing process flowchart for describing the method of forming the pattern by using the dual tone development process described with reference to FIGS. 19 and 20.

FIGS. 22 and 24 are plan views of a second mask used in a method of forming a pattern, according to an example embodiment and a comparative example embodiment of the inventive concept.

FIGS. 23 and 25 are plan views of a distribution of a light exposure intensity of a light exposure region when the light exposure is performed by using the second mask described with reference to FIGS. 22 and 24, respectively.

FIG. 26 is a schematic view of a manufacturing system used in a method of forming a pattern by using a dual tone development process according to an example embodiment of the inventive concept.

### DETAILED DESCRIPTION

Hereinafter, the inventive concept will now be described with reference to the accompanying drawings, in which example embodiments of the inventive concept are shown.

The inventive concept may, however, be embodied in different forms and should not be construed as limited to the embodiments set forth herein. Rather, these embodiments are provided so that this disclosure is thorough and complete and fully conveys the inventive concept to those skilled in the art. In the drawings, the thicknesses of layers and regions and the sizes of components may be exaggerated for clarity.

It will be understood that when an element, such as a layer, a region, or a substrate, is referred to as being “on”, “connected to” or “coupled to” another element, it may be directly on, connected or coupled to the other element or intervening elements may be present. Like reference numerals refer to like elements throughout.

It will be understood that, although the terms “first”, “second”, “third”, etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of example embodiments. For example, a first element could be termed a second element, and, similarly, a second element could be termed a first element, without departing from the scope of example embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “above” may encompass both an orientation of above and below. The device may be otherwise oriented (rotated 90 degrees or at other orientations) and spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region.

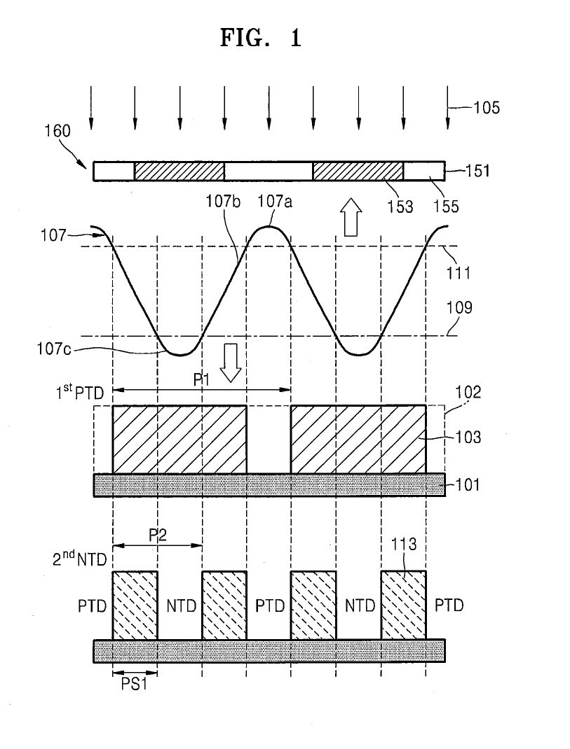

FIG. 1 is a cross-sectional view for describing a principle of a method of forming a pattern by using a dual tone development process according to an example embodiment of the inventive concept.

In detail, the method of forming the pattern by using the dual tone development process includes forming a dual tone photoresist layer 102 on a support layer 101. The support layer 101 may be a substrate, for example, a silicon substrate. The dual tone photoresist layer 102 may be a light sensitive layer. The dual tone photoresist layer 102 may be a radiation sensitive layer.

The dual tone photoresist layer 102 may be a photoresist layer, with respect to which positive tone development PTD or negative tone development NTD is performed according to a developing solution. The dual tone photoresist layer 102 may be a photoresist layer that reacts to light with a wavelength of 248 nm, a wavelength of 193 nm, a wavelength of 157 nm, a wavelength of extreme ultraviolet, or a combination thereof. The dual tone photoresist layer 102 may be a chemical amplification type photoresist layer.

The dual tone photoresist layer 102 may be exposed to the light by a light source 105 of a lithography device, by using a mask 160. The mask 160 may include mask patterns 153 which are separate from one another on a mask substrate 151, for example, a glass substrate. The mask patterns 153 may be an opaque portion. A portion 155 between the mask patterns 153 may be a transparent portion 155.

When the light source 105 passes through the mask 160, a light exposure profile 107 may be divided into a high-intensity profile portion 107a which has a high light exposure intensity, a middle-intensity profile portion 107b which has a middle light exposure intensity, and a low-intensity profile portion 107c which has a low light exposure intensity.

The division of the light exposure profile 107 may be executed by a lower critical line 109 and an upper critical line 111. The high-intensity profile portion 107a is above the upper critical line 111 which is indicated by an arrow toward an upper direction, the low-intensity profile portion 107c is below the lower critical line 109 which is indicated by an arrow toward a lower direction, and the middle-intensity profile portion 107b is a portion between the upper critical line 111 and the lower critical line 109.

The high-intensity profile portion 107a may be a portion corresponding to a portion around the center of the transparent portion 155 of the mask 160. The low-intensity profile portion 107c may be a portion corresponding to a portion around the center of the mask patterns 153 of the mask 160. The middle-intensity profile portion 107b may be a portion corresponding to a portion around an edge of the mask patterns 153 of the mask 160.

When a first positive tone development process 1^{st} PTD is performed after the light source 105 passes through the mask 160 and exposes the dual tone photoresist layer 102 to the light, a preliminary pattern 103 may be formed on the support layer 101. The positive tone development process may refer to a process that develops and removes the dual tone photoresist layer 102 corresponding to the high-intensity profile portion 107a. The positive tone development process may be a process that removes the dual tone photoresist layer 102 corresponding to the high-intensity profile portion 107a by using a first developing solution, for example, an alkali solution which has a hydrogen ion concentration higher than 7. The preliminary pattern 103 formed by the positive tone development process may have a pitch P1.

When a second negative tone development process 2^{nd} NTD is performed after the preliminary pattern 103 is formed by the first positive tone development process, a pattern 113 may be formed on the support layer 101. The negative tone development process may refer to a process that develops and removes the dual tone photoresist layer 102 corresponding to the low-intensity profile portion 107c. The negative tone development process may refer to a process that leaves the dual tone photoresist layer 102 corresponding to the middle-intensity profile portion 107b.

The negative tone development process may be a process that removes the dual tone photoresist layer 102 corresponding to the low-intensity profile portion 107c by using a second developing solution, for example, an organic acid solution. The organic acid solution may include normal butyl acetylene. The pattern 113 formed by the negative tone development process may have a pitch P2 which is smaller than the pitch P1 of the preliminary pattern 103. A width of the pattern 113 may correspond to the middle-intensity profile portion 107b and may be a width PS1. In FIG. 1, the positive tone development process is performed earlier than the negative tone development process. However, the negative tone development process may be performed earlier than the positive tone development process, according to necessity.

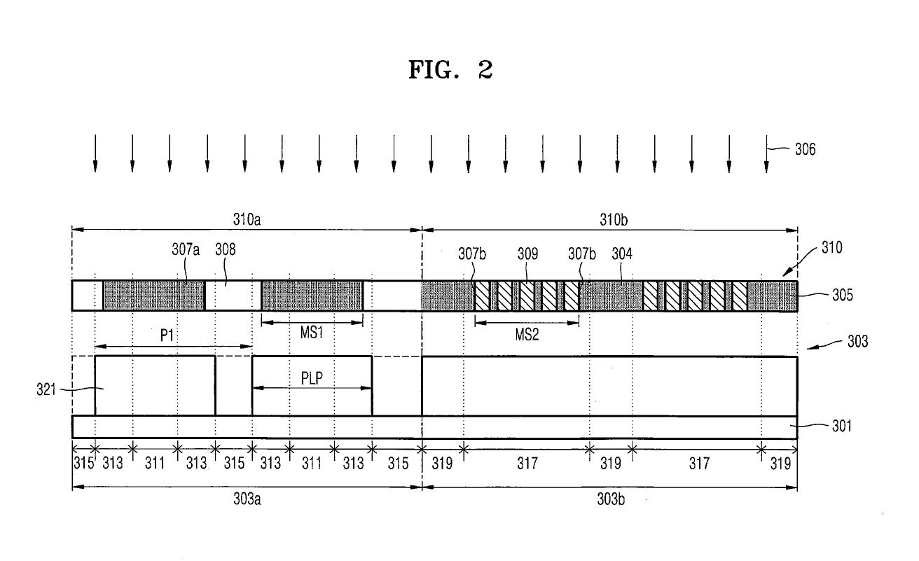

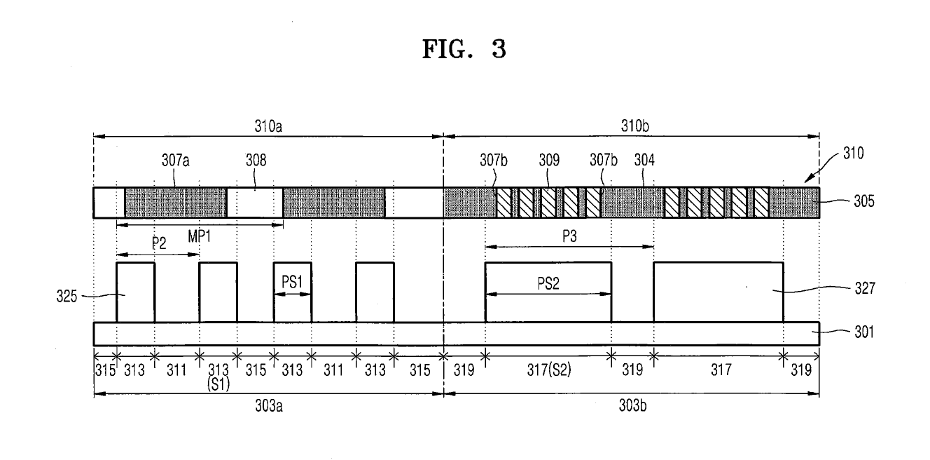

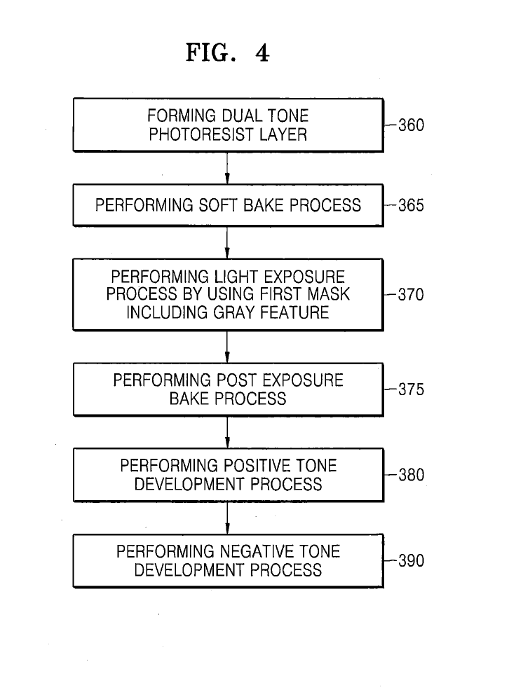

FIGS. 2 and 3 are cross-sectional views for describing a method of forming a pattern by using a dual tone development process according to an example embodiment of the inventive concept. FIG. 4 is a manufacturing process flowchart for describing the method of forming the pattern by using the dual tone development process of FIGS. 2 and 3.

In detail, the method of forming the pattern by using the dual tone development process includes forming a dual tone photoresist layer 303 on a support layer 301 (operation 360), as illustrated in FIGS. 2 and 4. The support layer 301 may correspond to reference numeral 101 of FIG. 1. The support layer 301 may be a substrate, for example, a silicon substrate. The dual tone photoresist layer 303 may be a light sensitive layer. The dual tone photoresist layer 303 may be a radiation sensitive layer.

The dual tone photoresist layer 303 may correspond to reference numeral 102 of FIG. 1. The dual tone photoresist layer 303 may be a photoresist layer, with respect to which positive tone development PTD or negative tone development NTD is performed according to a developing solution. The dual tone photoresist layer 303 may be a photoresist layer that reacts to light with a wavelength of 248 nm, a wavelength of 193 nm, a wavelength of 157 nm, a wavelength of extreme ultraviolet, or a combination thereof. The dual tone photoresist layer 303 may be a chemical amplification type photoresist layer.

The dual tone photoresist layer 303 may be divided into a first region 303a and a second region 303b. A pattern may be formed in the first region 303a by the dual tone development process described in reference to FIG. 1.

After the dual tone photoresist layer 303 is formed, a soft bake process may be performed in operation 365. The soft bake process may be performed by heating the dual tone photoresist layer 303 for about 1 to about 5 minutes at about 110 to about 120° C. . The soft bake process may harden the dual tone photoresist layer 303 and increase an adhesive strength with respect to the support layer 301. The soft bake process may be selectively performed.

A light exposure process is performed with respect to the dual tone photoresist layer 303 by a light source 306 of a lithography device by using a first mask 310 in operation 370, as illustrated in FIGS. 2 and 4. The first mask 310 may include a first mask region 310a and a second mask region 310b. The first mask region 310a and the second mask region 310b are illustrated to be adjacent to each other for convenience, and they may be separate from each other on a mask substrate 305. The first mask region 310a may correspond to reference numeral 160 of FIG. 1. The first mask 310 may include mask patterns 307a and 307b which are separate from each other on the mask substrate 305, for example, a glass substrate. The mask patterns 307a and 307b may be formed as polygons two-dimensionally.

The first mask pattern 307a of the first mask region 310a may be an opaque portion. A portion 308 between the first mask patterns 307a of the first mask region 310a may be a transparent portion. The first mask pattern 307a may have a width MS1. The width MS1 of the first mask pattern 307a may be smaller than a width PLP of a preliminary pattern 320 which is formed later.

The second mask pattern 307b may be formed in the second mask region 310b and a gray feature 309 may be formed in the second mask pattern 307b. The gray feature 309 may be a sub-resolution feature which is formed in the second mask pattern 307b. The second mask pattern 307b may be a semi-opaque portion. A portion 304 between the second mask patterns 307b may be an opaque portion.

The second mask pattern 307b may have a width MS2. The width MS2 of the second mask pattern 307b may be the same as or greater than the width MS1 of the first mask pattern 307a. The width MS2 of the second mask pattern 307b may be smaller than a width PS2 of a second pattern 327 which is formed later.

The dual tone photoresist layer 303 is exposed to light by using the first mask 310 including the first mask region 310a including the first mask pattern 307a and the second mask region 310b including the second mask pattern 307 including the gray feature 309. In this case, the first region 303a and the second region 303b of the dual tone photoresist layer 303 may have different light exposure intensities.

The first region 303a of the dual tone photoresist layer 303, that is, the first region 303a corresponding to the first mask region 310a, may be divided into a low light exposure region 311, a middle light exposure region 313, and a high light exposure region 315. The low light exposure region 311 may correspond to the low-intensity profile portion 107c of FIG. 1. The middle light exposure region 313 may correspond to the middle-intensity profile portion 107b of FIG. 1. The high light exposure region 315 may correspond to the high-intensity profile portion 107a of FIG. 1.

Unlike the first region 303a, the second region 303b of the dual tone photoresist layer 303, that is, the second region 303b corresponding to the second mask region 310b, may be divided into a low light exposure region 319 and a middle light exposure region 317, due to the gray feature 309. The second region 303b of the dual tone photoresist layer 303, which corresponds to the second mask region 310b, may not include a high-intensity light exposure region. The light exposure intensity of the dual tone photoresist layer 303 corresponding to the second mask region 310b will be described in more detail later.

The low light exposure region 319 may correspond to the low-intensity profile portion 107c of FIG. 1. The low light exposure region 319 of the second region 303b may correspond to the low light exposure region 311 of the first region 303a. The middle light exposure region 317 may correspond to the middle-intensity profile portion 107b of FIG. 1. The middle light exposure region 317 of the second region 303b may correspond to the middle light exposure region 313 of the first region 303a.

After a light exposure process is performed, a post exposure bake process may be performed in operation 375. The post exposure bake process may be performed by heating the dual tone photoresist layer 303 which is exposed to light at about 110° C. The post exposure bake process may harden the dual tone photoresist layer 303 which is exposed to light. The post exposure bake process may be selectively performed.

The positive tone development process is performed in the dual tone photoresist layer 303 in operation 380 as illustrated in FIGS. 2 and 4. In the case in which the first positive tone development process is performed as illustrated in FIG. 2, a preliminary pattern 321 may be formed in the first region 303a and the dual tone photoresist layer 303 may remain in the second region 303b.

The positive tone development process may refer to a process that develops and removes the dual tone photoresist layer 303 corresponding to the high light exposure region 315 of the first region 303a. The positive tone development process may be a process that removes the dual tone photoresist layer 303 corresponding to the high light exposure region 315 by using a first developing solution, for example, an alkali solution which has a hydrogen ion concentration which is greater than 7. The preliminary pattern 321 formed by the positive tone development process may have a pitch P1. The preliminary pattern 321 may have a width PLP.

The negative tone development process is performed in the dual tone photoresist layer 303 in operation 390 as illustrated in FIGS. 3 and 4. In the case in which the second negative tone development process is performed after the preliminary pattern 321 is formed by performing the first positive tone development process, a first pattern 325 and a second pattern 327 may be formed respectively in the first region 303a and the second region 303b.

A shape of the first pattern 325 may be defined by the preliminary pattern 321. The first pattern 325 may be a line space pattern. The first pattern 325 may be a hole pattern in which a hole is formed. The second pattern 327 may be a bulk pattern. The second pattern 327 may be a polygonal pattern as will be described later. The second pattern 327 may be a polygonal pattern having round corners as will be described later.

The negative tone development process may refer to a process that develops and removes the dual tone photoresist layer 303 corresponding to the low light exposure regions 311 and 319. The negative tone development process may refer to a process that leaves the dual tone photoresist layer 303 corresponding to the middle light exposure regions 313 and 317.

The negative tone development process may be a process that removes the dual tone photoresist layer 303 corresponding to the low light exposure regions 311 and 319 by using a second developing solution, for example, an organic acid solution. The organic acid solution may include normal butyl acetylene.

The first pattern 325 formed by the negative tone development process may have a pitch P2 which is smaller than the pitch P1 of the preliminary pattern 321. A width of the first pattern 325 may correspond to a width S1 of the middle light exposure region 313 and be a width PS1. The pitch P2 of the first pattern 325 may be smaller than a pitch MP1 of the mask patterns 307a and 307b.

The second pattern 327 formed by the negative tone development process may have a pitch P3 which is the same as or larger than the pitch P1 of the preliminary pattern 321. The second patterns 327 may have the pitch P3 which is greater than the pitch P2 of the first patterns 325. A width of the second pattern 327 may correspond to a width S2 of the middle light exposure region 317 and be a width PS2. Accordingly, the width of the second pattern 327 may be greater than that of the first pattern 325, and the second pattern 327 may be formed as a bulk pattern of a greater area.

In FIGS. 2 through 4, the positive tone development process is performed earlier than the negative tone development process. However, according to necessity, the negative tone development process may be performed earlier than the positive tone development process.

The method of forming the pattern by using the dual tone development process according to the present example embodiment may include exposing the dual tone photoresist layer 303 to light by using the first mask 310 having the gray feature 309. The first mask 310 may include the gray feature 309 included in the second mask pattern 307b.

The dual tone photoresist layer 303 which is exposed to the light by using the first mask 310 may be patterned by the positive development process and the negative development process, thereby forming the pattern 325 having the smaller pitch than the mask pattern 307a, the patterns 325 and 327 having pitches of different sizes, or the bulk pattern 327 of various shapes. That is, according to the method of forming the pattern according to the present example embodiment, various patterns, such as an insulating pattern, a test pattern, an overlay pattern, and an align pattern, may be formed without a limitation with regard to pitches.

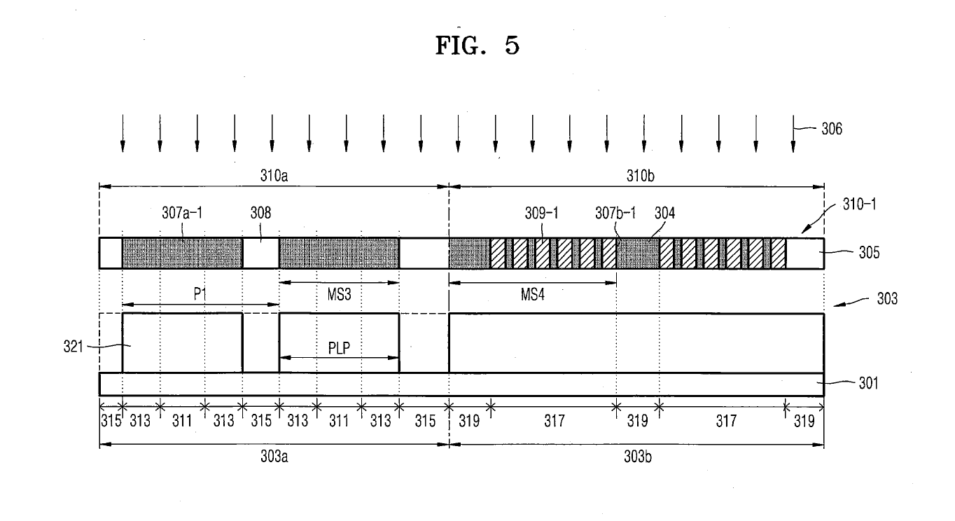

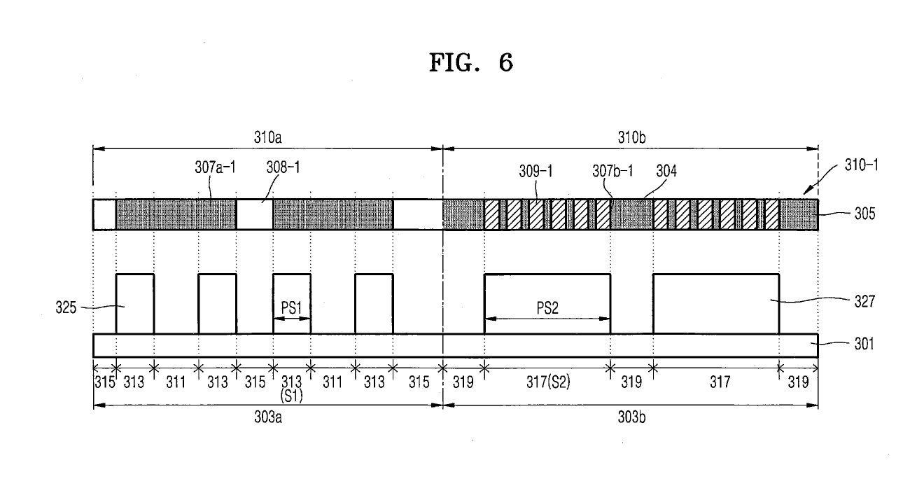

FIGS. 5 and 6 are cross-sectional views for describing a method of forming a pattern by using a dual tone development process according to an example embodiment of the inventive concept.

In detail, the method of forming the pattern by using the dual tone development process of FIGS. 5 and 6 are the same as the method of forming the pattern by using the dual tone development process of FIGS. 2 and 4, except for a different shape of a mask 310-1. In FIGS. 5 and 6, like reference numerals denote like elements in FIGS. 2 through 4.

FIG. 5 is a cross-sectional view that illustrates forming of the dual tone photoresist layer 303 (operation 360), exposing of the dual tone photoresist layer 303 to light (operation 370), and performing of the positive tone development process in the dual tone photoresist layer 303 (operation 380).

When exposing the dual tone photoresist layer 303 to light, the mask 310-1 may be used. The first mask 310-1 may include the first mask region 310a and the second mask region 310b. Unlike FIG. 2, a width MS3 of a first mask pattern 307a-1 of the first mask region 310a may be the same as the width PLP of the preliminary pattern 321 to be formed later. The width MS3 of the first mask pattern 307a-1 may be greater than the width MS1 of the first mask pattern 307a of FIG. 2. While the width MS3 of the first mask pattern 307a-1 may be greater than the width MS1 of the first mask pattern 307a of FIG. 2, the preliminary pattern 321 and the first pattern 325 which are to be formed later may have the same width.

Unlike FIG. 2, a width MS4 of a second mask pattern 307b-1 of the second mask region 310b may be the same as the width PS2 of the second pattern 327 to be formed later. The width MS4 of the second mask pattern 307b-1 may be greater than the width MS2 of the second mask pattern 307b of FIG. 2. A gray feature 309-1 formed in the second mask pattern 307b-1 may include a higher number of features, compared to FIG. 2.

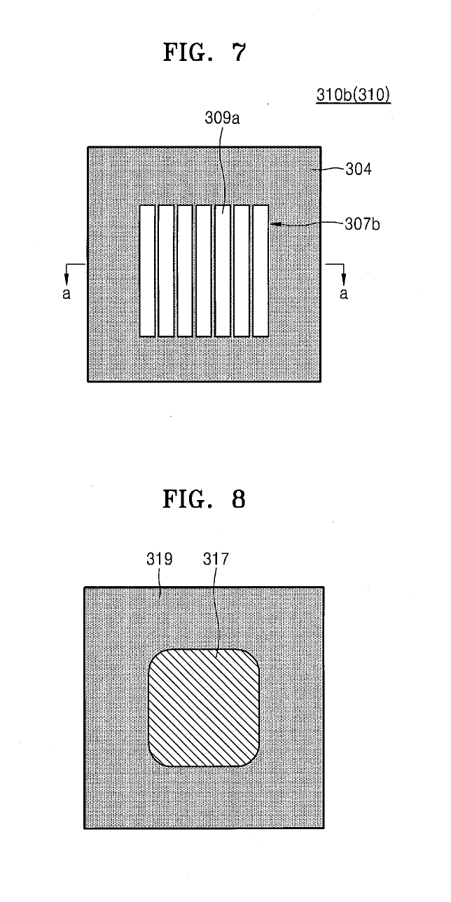

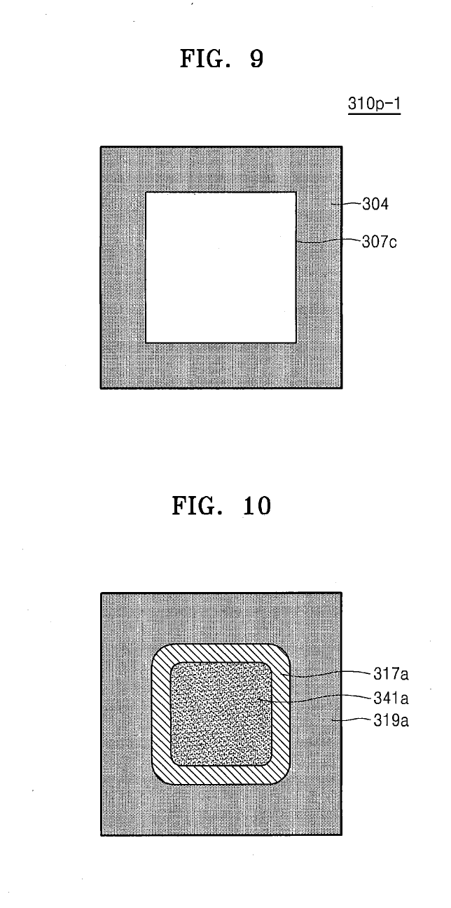

FIGS. 7 and 9 are plan views of a first mask used in a method of forming a pattern, according to an example embodiment and a comparative example embodiment of the inventive concept. FIGS. 8 and 10 are plan views of a distribution of a light exposure intensity of a light exposure region when the light exposure is performed by using the first mask of FIGS. 7 and 9, respectively.

In detail, FIG. 7 is a plan view illustrating part of the first mask 310 and the second mask region 310b of FIG. 2. The second mask region 310b illustrated in FIG. 2 may be an essential cross-sectional view taken along a line a-a of FIG. 7. A gray feature 309a of FIG. 7 may be the gray feature 309 of FIG. 2.

The gray feature 309a may be a sub-resolution feature which is formed in the mask pattern 307b. The number of features may be dependent on a size of the mask pattern 307b. The mask pattern 307b may be a square pattern.

A comparative mask 310p-1 for a comparison with FIG. 7 is a case in which a gray feature is not formed in a mask pattern 307c. In FIGS. 7 and 9, reference numeral 304 may refer to an opaque layer.

FIG. 8 illustrates the distribution of the light exposure intensity of the light exposure region when the light exposure is performed by using the first mask 310 illustrated in FIG. 7. As illustrated in FIG. 8, a portion corresponding to the mask pattern 307b in which the gray feature is formed is the middle light exposure region 317 of a square shape having round corners, and the low light exposure region 319 may surround the middle light exposure region 317.

The low light exposure region 319 may be removed by the negative tone development process as described in reference to FIG. 3. Thus, when the gray feature 309a is formed in the mask pattern 307b, the second pattern 327 of a square bulk shape may be formed by the negative tone development process as illustrated in FIG. 3.

On the contrary, FIG. 10 illustrates the distribution of the light exposure intensity of the light exposure region when the light exposure is performed by using the comparative mask 310p-1 illustrated in FIG. 9. As illustrated in FIG. 9, a center of a portion corresponding to the mask pattern 307c is a high light exposure region 341a of a square shape having round corners. The high light exposure region 341a is surrounded by a middle light exposure region 317a of a band shape. The middle light exposure region 317a is surrounded by a low light exposure region 319a.

The high light exposure region 341 a and the low light exposure region 319a may be removed by the positive development process and the negative development process as described in FIGS. 2 and 3, but the middle light exposure region 317a may remain after the dual tone development process. Thus, when the light exposure is performed by using the comparative mask 310p-1 of FIG. 9, the band shape pattern remains and thus a square bulk shape pattern is not formed.

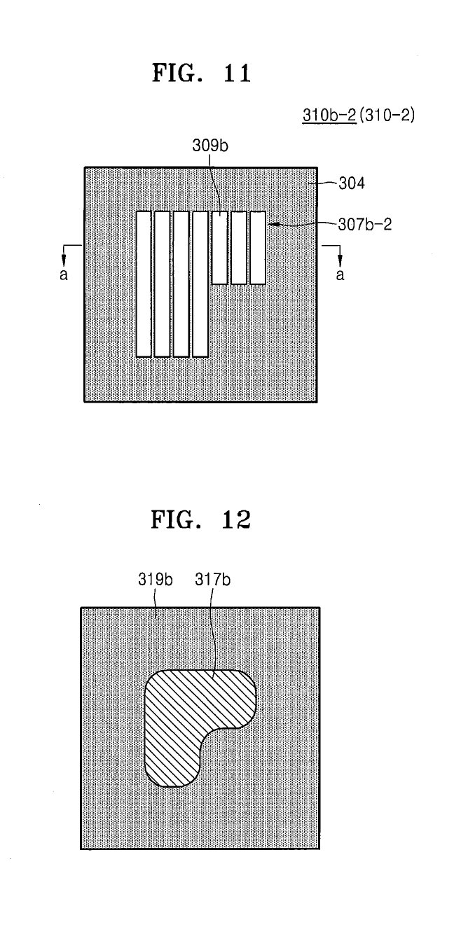

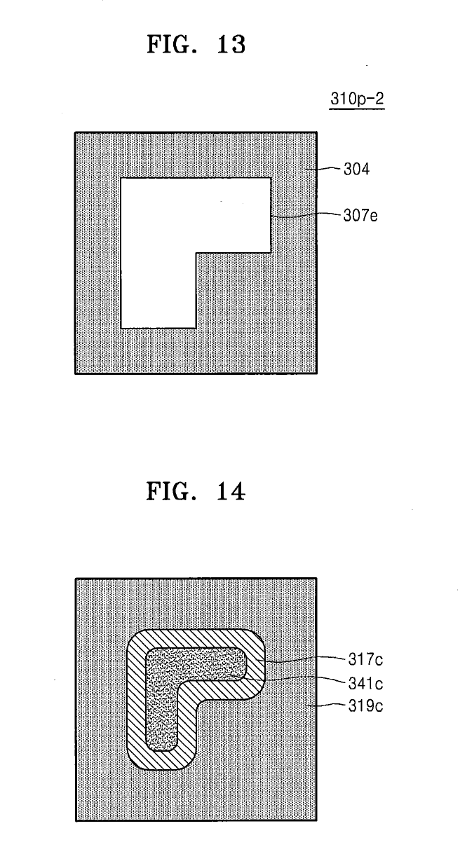

FIGS. 11 and 13 are plan views of a first mask used in a method of forming a pattern, according to an example embodiment and a comparative example embodiment of the inventive concept. FIGS. 12 and 14 are plan views of a distribution of a light exposure intensity of a light exposure region when the light exposure is performed by using the first mask of FIGS. 11 and 13, respectively.

In detail, a first mask 301-2 and a second mask region 310b-2 of FIG. 11 may be the same as the first mask 310 and the second mask region 310b of FIG. 7, except for a shape of a mask pattern 307b-2.

FIG. 11 is a plan view illustrating part of the first mask 310 and the second mask region 310b of FIG. 2. The second mask region 310b illustrated in FIG. 2 may be an essential cross-sectional view taken along a line a-a of FIG. 11. A gray feature 309b of FIG. 11 may be the gray feature 309 of FIG. 2.

The gray feature 309b may be a sub-resolution feature which is formed in the mask pattern 307b-2. The number of features may be dependent on a size of the mask pattern 307b-2. The mask pattern 307b-2 may be a polygonal pattern including a big rectangle on a left side and a small rectangle on a right side.

A comparative mask 310p-2 for a comparison with FIG. 11 is a case in which a gray feature is not formed in a mask pattern 307e. In FIGS. 11 and 13, reference numeral 304 may refer to an opaque layer.

FIG. 12 illustrates the distribution of the light exposure intensity of the light exposure region when the light exposure is performed by using the first mask 310-2 illustrated in FIG. 11. As illustrated in FIG. 12, a portion corresponding to the first mask pattern 307b-2 in which the gray feature is formed is a middle light exposure region 317b of a polygonal shape having round corners, and a low light exposure region 319b may surround the middle light exposure region 317b.

The low light exposure region 319b may be removed by the negative tone development process as described in FIG. 3. Thus, when the mask pattern 307b-2 has a polygonal shape and the gray feature 309a is formed in the mask pattern 307b-2, the second pattern 327 of a polygonal bulk shape may be formed by the negative tone development process as illustrated in FIG. 3.

On the contrary, FIG. 14 illustrates the distribution of the light exposure intensity of the light exposure region when the light exposure is performed by using the comparative mask 310p-2 illustrated in FIG. 13. As illustrated in FIG. 14, a center of a portion corresponding to the mask pattern 307e is a high light exposure region 341c of a polygonal shape having round corners. The high light exposure region 341c is surrounded by a middle light exposure region 317c of a band shape. The middle light exposure region 317c is surrounded by a low light exposure region 319c.

The high light exposure region 341c and the low light exposure region 319c may be removed by the positive development process and the negative development process as described in FIGS. 2 and 3, but the middle light exposure region 317c may remain after the dual tone development process. Thus, when the light exposure is performed by using the comparative mask 310p-2 of FIG. 14, the band shape pattern is formed and thus a polygonal bulk shape pattern is not formed.

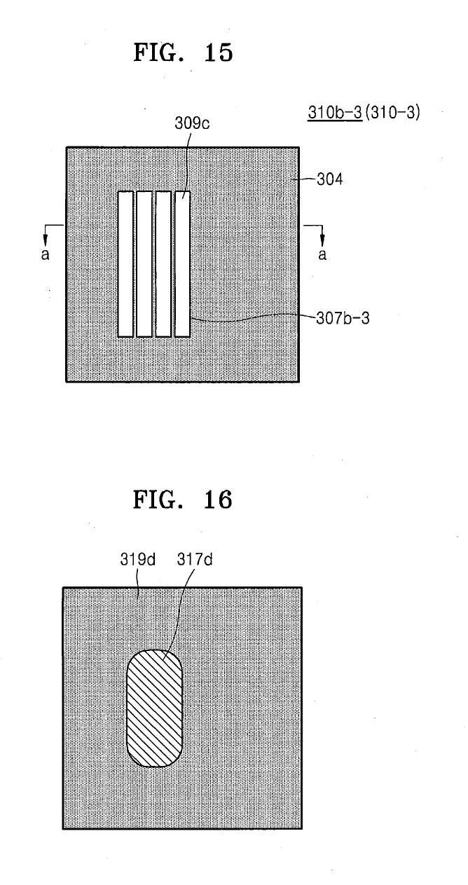

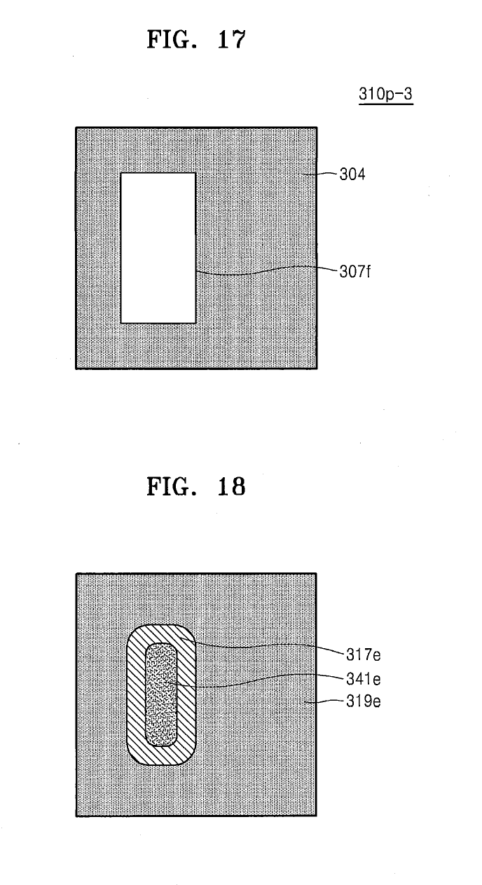

FIGS. 15 and 17 are plan views of a first mask used in a method of forming a pattern, according to an example embodiment and a comparative example embodiment of the inventive concept. FIGS. 16 and 18 are plan views of a distribution of a light exposure intensity of a light exposure region when the light exposure is performed by using the first mask of FIGS. 15 and 17, respectively.

In detail, a first mask 301-3 and a second mask region 310b-3 of FIG. 15 may be the same as the first mask 310 and the second mask region 310b of FIG. 7, except for a shape of a mask pattern 307b-3.

FIG. 15 is a plan view illustrating part of the first mask 310 and the second mask region 310b of FIG. 2. The second mask region 310b illustrated in FIG. 2 may be an essential cross-sectional view taken along a line a-a of FIG. 15. A gray feature 309c of FIG. 15 may be the gray feature 309 of FIG. 2.

The gray feature 309c may be a sub-resolution feature which is formed in the mask pattern 307b-3. The number of features may be dependent on a size of the mask pattern 307b-3. The mask pattern 307b-3 may be a rectangular pattern. A comparative mask 310p-3 for a comparison with FIG. 17 is a case in which a gray feature is not formed in a mask pattern 307f. In FIGS. 15 and 17, reference numeral 304 may refer to an opaque layer.

FIG. 16 illustrates the distribution of the light exposure intensity of the light exposure region when the light exposure is performed by using the first mask 310-3 illustrated in FIG. 15. As illustrated in FIG. 16, a portion corresponding to the first mask pattern 307b-3 in which the gray feature is formed is a middle light exposure region 317d of a square shape having round corners, and a low light exposure region 319d may surround the middle light exposure region 317d.

The low light exposure region 319d may be removed by the negative tone development process as described in FIG. 3. Thus, when the gray feature 309a is formed in the mask pattern 307b-3, the second pattern 327 of a rectangular bulk shape may be formed by the negative tone development process as illustrated in FIG. 3.

On the contrary, FIG. 18 illustrates the distribution of the light exposure intensity of the light exposure region when the light exposure is performed by using the comparative mask 310p-3 illustrated in FIG. 17. As illustrated in FIG. 18, a center of a portion corresponding to the mask pattern 307f is a high light exposure region 341e of a square shape having round corners. The high light exposure region 341e is surrounded by a middle light exposure region 317e of a band shape. The middle light exposure region 317e is surrounded by a low light exposure region 319e.

The high light exposure region 341e and the low light exposure region 319e may be removed by the positive development process and the negative development process as described in FIGS. 2 and 3, but the middle light exposure region 317e may remain after the dual tone development process. Thus, when the light exposure is performed by using the comparative mask 310p-e of FIG. 18, the band shape pattern remains and thus a rectangular bulk shape pattern is not formed.

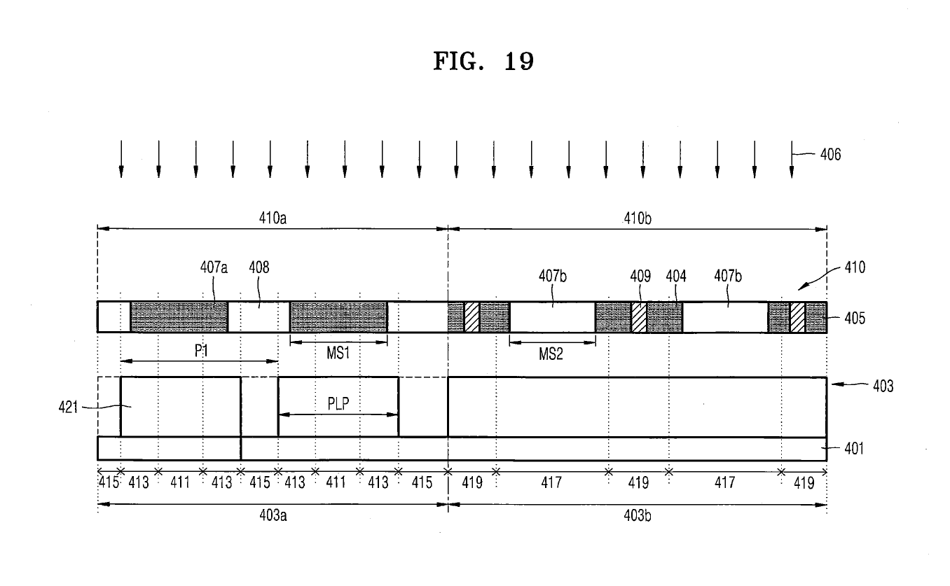

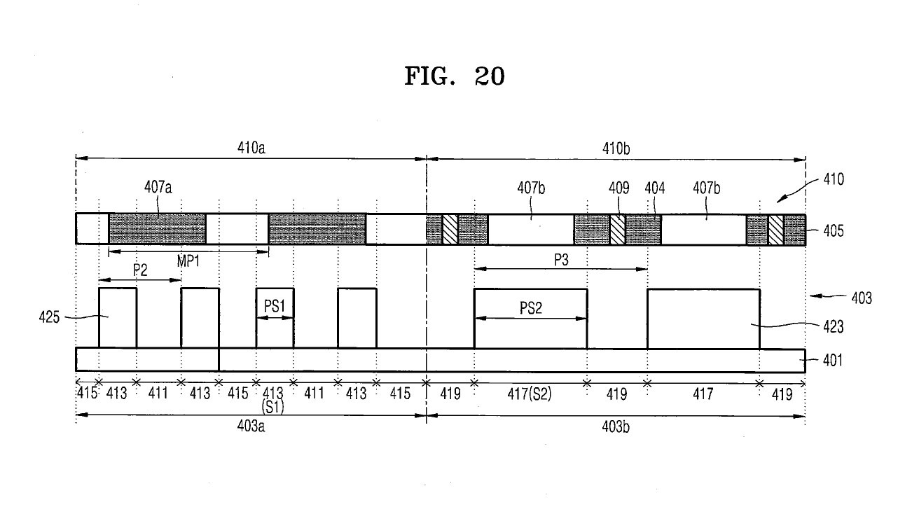

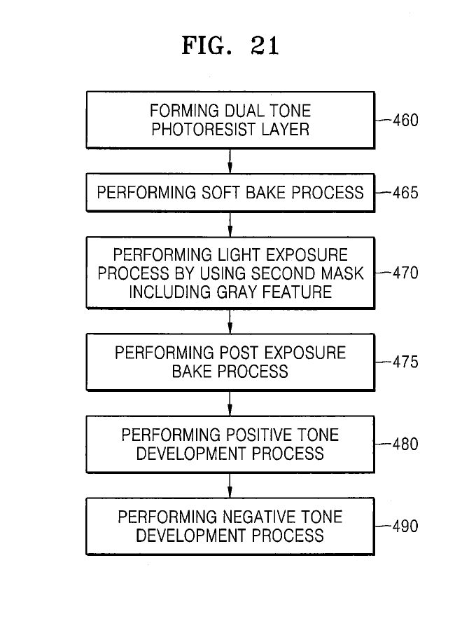

FIGS. 19 and 20 are cross-sectional views for describing a method of forming a pattern by using a dual tone development process according to an example embodiment of the inventive concept. FIG. 21 is a manufacturing process flowchart for describing the method of forming the pattern by using the dual tone development process of FIGS. 19 and 20.

In detail, the method of forming the pattern by using the dual tone development process includes forming a dual tone photoresist layer 403 on a support layer 401 (operation 460), as illustrated in FIGS. 19 and 20. Operation 460 corresponds to operation 360 described in FIGS. 2 and 4, and thus, its description will not be repeated. The dual tone photoresist layer 403 may be divided into a first region 403a and a second region 403b, as in FIG. 2.

A pattern may be formed in the first region 403a by the dual tone development process described in FIG. 1. After the dual tone photoresist layer 403 is formed, a soft bake process may be performed in operation 465. Operation 465 may correspond to step 365 described in FIGS. 2 and 4.

A light exposure process is performed with respect to the dual tone photoresist layer 403 by a light source 406 of a lithography device by using a second mask 410 in operation 470, as illustrated in FIGS. 19 and 21. The second mask 410 may include a first mask region 410a and a second mask region 410b. The first mask region 410a and the second mask region 410b are illustrated to be adjacent to each other for convenience, and they may be separate from each other on a mask substrate 405.

The first mask region 410a may correspond to reference numeral 160 of FIG. 1. The first mask region 410a may correspond to the first mask region 310a of FIG. 2. The second mask 410 may include mask patterns 407a and 407b which are separate from each other on the mask substrate 405, for example, a glass substrate. The mask patterns 407a and 407b may be polygons two-dimensionally.

The first mask pattern 407a of the first mask region 410a may be an opaque portion. A portion 408 between the first mask patterns 407a of the first mask region 410a may be a transparent portion. The first mask pattern 407a may have a width MS1. The width MS1 of the first mask pattern 407a may be smaller than a width PLP of a preliminary pattern 421 which is formed later.

The second mask pattern 407b may be formed in the second mask region 410b and a gray feature 409 may be formed between the second mask patterns 407b. The gray feature 409 may be a sub-resolution feature which is formed between the second mask patterns 407b. The gray feature 409 may serve a function of adjusting a shape of a second pattern 423 which is formed later. A portion 304 between the second mask patterns 407b may be an opaque portion.

The second mask pattern 407b may have a width MS2. The width MS2 of the second mask pattern 407b may be the same as or greater than the width MS1 of the first mask pattern 407a. The width MS2 of the second mask pattern 407b may be smaller than a width PS2 of the second pattern 423 which is formed later.

The dual tone photoresist layer 403 is exposed to light by using the second mask 410 including the first mask region 410a including the first mask pattern 407a and the second mask region 410b including the gray feature 409 between the second mask patterns 407b. In this case, the first region 403a and the second region 403b of the dual tone photoresist layer 403 may have different light exposure intensities.

The first region 403a of the dual tone photoresist layer 403, that is, the first region 403a corresponding to the first mask region 410a, may be divided into a low light exposure region 411, a middle light exposure region 413, and a high light exposure region 415. The low light exposure region 411 may correspond to the low-intensity profile portion 107c of FIG. 1. The middle light exposure region 413 may correspond to the middle-intensity profile portion 107b of FIG. 1. The high light exposure region 415 may correspond to the high-intensity profile portion 107a of FIG. 1.

Unlike the first region 403a, the second region 403b of the dual tone photoresist layer 403, that is, the second region 403b corresponding to the second mask region 410b, may be divided into a low light exposure region 419 and a middle light exposure region 417, due to the gray feature 409. The second region 403b of the dual tone photoresist layer 403, which corresponds to the second mask region 410b, may not include a high-intensity light exposure region. The light exposure intensity of the dual tone photoresist layer 403 corresponding to the second mask region 410b will be described in more detail later.

The low light exposure region 419 may correspond to the low-intensity profile portion 107c of FIG. 1. The low light exposure region 419 of the second region 403b may correspond to the low light exposure region 411 of the first region 403a. The middle light exposure region 417 may correspond to the middle-intensity profile portion 107b of FIG. 1. The middle light exposure region 417 of the second region 403b may correspond to the middle light exposure region 413 of the first region 403a.

After a light exposure process is performed, a post exposure bake process may be performed in operation 475. The post exposure bake process may correspond to operation 375 of FIG. 4. The post exposure bake process may be performed by heating the dual tone photoresist layer 403 which is exposed to light at about 110° C. . The post exposure bake process may harden the dual tone photoresist layer 403 which is exposed to light. The post exposure bake process may be selectively performed.

The positive tone development process is performed in the dual tone photoresist layer 403 in operation 480. In the case in which the first positive tone development process is performed as illustrated in FIG. 2, a preliminary pattern 421 may be formed in the first region 403a and the dual tone photoresist layer 403 may remain in the second region 403b.

The positive tone development process may refer to a process that develops and removes the dual tone photoresist layer 403 corresponding to the high light exposure region 415 of the first region 403a. The positive tone development process may be a process that removes the dual tone photoresist layer 403 corresponding to the high light exposure region 415 by using a first developing solution, for example, an alkali solution which has a hydrogen ion concentration which is greater than 7. The preliminary pattern 421 formed by the positive tone development process may have a pitch P1. The preliminary pattern 421 may have a width PLP.

The negative tone development process is performed in the dual tone photoresist layer 403 in operation 490 as illustrated in FIGS. 20 and 21. In the case in which the second negative tone development process is performed after the preliminary pattern 421 is formed by performing the first positive tone development process, a first pattern 425 and a second pattern 423 may be formed respectively in the first region 403a and the second region 403b.

A shape of the first pattern 425 may be defined by the preliminary pattern 421. The first pattern 425 may be a line space pattern. The first pattern 425 may be a hole pattern in which a hole is formed. The second pattern 423 may be a bulk pattern. The second pattern 423 may be a circular pattern as will be described later. The second pattern 423 may be a circular pattern having round corners as will be described later.

The negative tone development process may refer to a process that develops and removes the dual tone photoresist layer 403 corresponding to the low light exposure regions 411 and 419. The negative tone development process may refer to a process that leaves the dual tone photoresist layer 403 corresponding to the middle light exposure regions 413 and 417.

The negative tone development process may be a process that removes the dual tone photoresist layer 403 corresponding to the low light exposure regions 411 and 419 by using a second developing solution, for example, an organic acid solution. The organic acid solution may include normal butyl acetylene. The first pattern 425 formed by the negative tone development process may have a pitch P2 which is smaller than the pitch P1 of the preliminary pattern 421. A width of the first pattern 425 may correspond to a width S1 of the middle light exposure region 413 and be a width PS1. The pitch P2 of the first pattern 425 may be smaller than a pitch MP1 of the mask patterns 407a and 407b.

The second pattern 423 formed by the negative tone development process may have a pitch P3 which is the same as or larger than the pitch P1 of the preliminary pattern 421. The second patterns 423 may have the pitch P3 which is greater than the pitch P2 of the first patterns 425. A width of the second pattern 423 may correspond to a width S2 of the middle light exposure region 417 and be a width PS2. Accordingly, the width of the second pattern 423 may be greater than that of the first pattern 425, and the second pattern 423 may be formed as a bulk pattern of a greater area.

In FIGS. 19 through 21, the positive tone development process is performed earlier than the negative tone development process. However, according to necessity, the negative tone development process may be performed earlier than the positive tone development process.

The method of forming the pattern by using the dual tone development process according to the present example embodiment may include exposing the dual tone photoresist layer 403 to light by using the second mask 410 having the gray feature 409. The second mask 410 may include the gray feature 409 included between the second mask patterns 407b. The dual tone photoresist layer 403 which is exposed to the light by using the second mask 410 may be patterned by the positive development process and the negative development process, thereby forming the pattern 425 having the smaller pitch than the mask pattern 407a, the patterns 425 and 423 having pitches of different sizes, or the bulk pattern 423 of various shapes. That is, according to the method of forming the pattern according to the present example embodiment, various patterns, such as an insulating pattern, a test pattern, an overlay pattern, and an align pattern, may be formed without a limitation with regard to pitches.

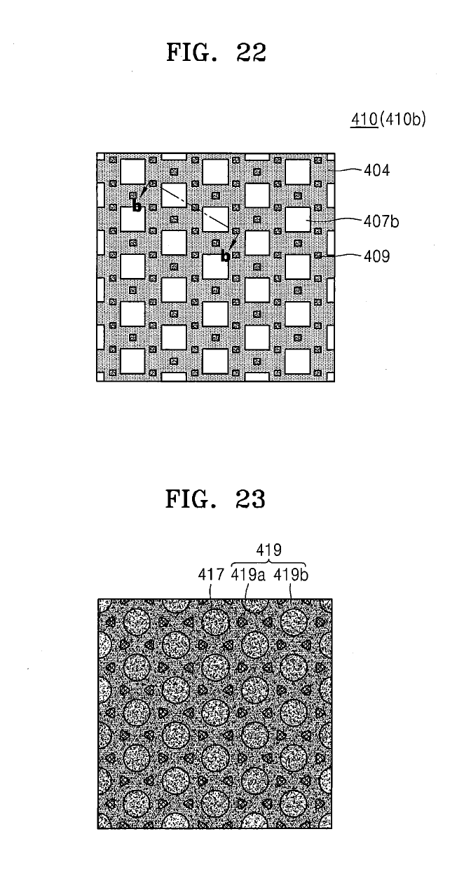

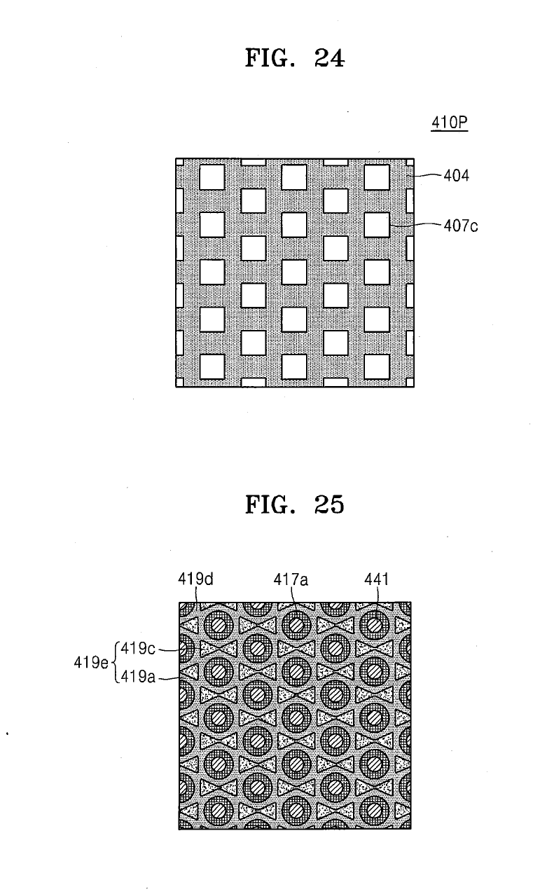

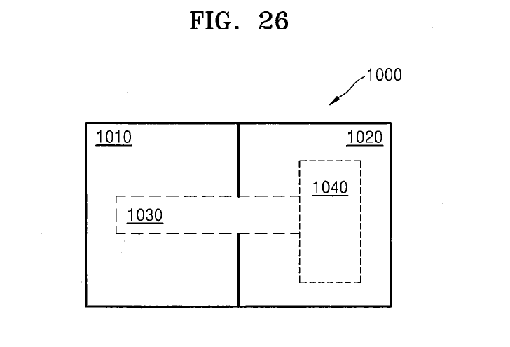

FIGS. 22 and 24 are plan views of a second mask used in a method of forming a pattern, according to an example embodiment and a comparative example embodiment of the inventive concept. FIGS. 23 and 25 are plan views of a distribution of a light exposure intensity of a light exposure region when the light exposure is performed by using the second mask of FIGS. 22 and 24, respectively.

In detail, FIG. 22 is a plan view illustrating part of the first mask 410 and the second mask region 410b of FIG. 20. The second mask region 410b illustrated in FIG. 20 may be an essential cross-sectional view taken along a line b-b of FIG. 22. The gray feature 409 of FIG. 22 may be the gray feature 409 of FIG. 20.

The gray feature 409 may be a sub-resolution feature which is formed in the mask patterns 407b. The number of features may be dependent on a size of the mask pattern 407b. The mask pattern 407b may be a square pattern.

A comparative mask 410p for a comparison with FIG. 22 is a case in which a gray feature is not formed between the mask patterns 407c. In FIGS. 22 and 24, reference numeral 404 may refer to an opaque layer.

FIG. 23 illustrates the distribution of the light exposure intensity of the light exposure region when the light exposure is performed by using the second mask 410 illustrated in FIG. 22. As illustrated in FIG. 23, a portion corresponding to the mask pattern 407b is a middle light exposure region 417 of a circular shape, and a low light exposure region 419 may surround the middle light exposure region 417. The low light exposure region 419 may include a first low light exposure region 419a and a second low light exposure region 419b which has a slightly higher light exposure intensity than the first low light exposure region 419a.

The low light exposure region 419 may be removed by the negative tone development process as described in FIG. 3. Thus, when the gray feature 409 is formed between the mask patterns 407b, the second pattern 423 of a circular bulk shape may be formed by the negative tone development process as illustrated in FIG. 21.

On the contrary, FIG. 25 illustrates the distribution of the light exposure intensity of the light exposure region when the light exposure is performed by using the comparative mask 410p illustrated in FIG. 24. As illustrated in FIG. 25, a center of a portion corresponding to the mask pattern 407 is a high light exposure region 441 of a circular shape. The high light exposure region 441 is surrounded by a middle light exposure region 417a of a circular band shape. The middle light exposure region 417a is surrounded by a low light exposure region 419e. The low light exposure region 419e may include a first low light exposure region 419c and a second low light exposure region 419d which has a slightly higher light exposure intensity than the first low light exposure region 419c.

The high light exposure region 441 and the low light exposure region 419e may be removed by the positive development process and the negative development process as described in FIGS. 19 and 20, but the middle light exposure region 417a may remain after the dual tone development process. Thus, when the light exposure is performed by using the comparative mask 310p-1 of FIG. 25, the band shape pattern remains and thus a circular bulk shape pattern is not formed.

FIG. 26 is a schematic view of a manufacturing system used in a method of forming a pattern by using a dual tone development process according to an example embodiment of the inventive concept.

In detail, the manufacturing system 1000 used in the method of forming the pattern by using the dual tone development process may include a support layer, a track device 1010 that coats a substrate with a dual tone photoresist layer, a lithography device 1020 that exposes the dual tone photoresist layer to light, and a support layer between the track device 1010 and the lithography device 1020, for example, a transportation device 1030 that transports the substrate.

The track device 1010 may be a device that coats the support layer with the dual tone photoresist layer by spin coating. The lithography device 1020 may include a light exposure device 1040 that exposes the dual tone photoresist layer to light by a light source by using a mask. In the manufacturing system 1000, the track device 1010, the lithography device 1020, and the transportation device 1030 may be combined to be formed as one system.

While the inventive concept has been particularly shown and described with reference to example embodiments thereof, it will be understood that various changes in form and details may be made therein without departing from the spirit and scope of the following claims. The appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A method of forming a pattern, the method comprising:
forming a dual tone photoresist layer on a support layer;
forming a low light exposure region, a middle light exposure region and a high light exposure region in a first region of the dual tone photoresist layer and forming a low light exposure region and a middle light exposure region in a second region of the dual tone photoresist layer by exposing the dual tone photoresist layer to light by using a mask comprising a gray feature;
forming a plurality of preliminary patterns in the first region by removing the dual tone photoresist layer in the high light exposure region of the first region by performing a positive development process; and
forming a plurality of first patterns which are spaced apart from one another in the first region and a plurality of second patterns which are spaced apart from one another in the second region by removing the dual tone photoresist layer in the low light exposure region of the first region and the dual tone photoresist layer in the low light exposure region of the second region by performing a negative development process.

2. The method of claim 1, wherein the plurality of first patterns have pitches smaller than pitches of the plurality of preliminary patterns.

3. The method of claim 1, wherein the plurality of second patterns have pitches larger than pitches of the plurality of first patterns.

4. The method of claim 1, wherein the plurality of second patterns are bulk patterns.

5. The method of claim 1, wherein the plurality of second patterns are polygonal patterns or circular patterns.

6. The method of claim 1, wherein the mask comprises a plurality of mask patterns which are spaced apart from one another on a mask substrate, and the gray feature comprises a sub-resolution feature which is formed in the plurality of mask patterns which expose the second region to light.

7. The method of claim 6, wherein sizes of the plurality of mask patterns are the same as or smaller than sizes of the plurality of preliminary patterns and the plurality of second patterns.

8. The method of claim 1, wherein the mask comprises a plurality of mask patterns which are spaced apart from one another on a mask substrate, and the gray feature comprises a sub-resolution feature which is formed between the plurality of mask patterns which expose the second region to light.

9. The method of claim 1, wherein the mask comprises a plurality of polygonal mask patterns which are spaced apart from one another on a mask substrate, and the plurality of second patterns comprise a plurality of polygonal patterns which are disposed on the support layer and comprises round corners.

10. The method of claim 1, wherein the mask comprises a plurality of circular mask patterns which are spaced apart from one another on a mask substrate, and the plurality of second patterns comprise a plurality of circular patterns which are spaced apart from one another on the support layer and comprise round shapes.

11. A method of forming a pattern, the method comprising:
forming a dual tone photoresist layer on a support layer;
forming a low light exposure region, a middle light exposure region and a high light exposure region in a first region of the dual tone photoresist layer and forming a low light exposure region and a middle light exposure region in a second region of the dual tone photoresist layer by exposing the dual tone photoresist layer to light by using a mask in which a plurality of mask patterns that are spaced apart from one another in the first mask region and the second mask region and a gray feature that is formed in the second mask region are arranged, the first region corresponding to a first mask region and the second region corresponding to a second mask region;
forming a plurality of preliminary patterns in the first region by removing the dual tone photoresist layer in the high light exposure region of the first region by performing a positive development process; and
forming a plurality of first patterns which are spaced apart from one another in the middle light exposure region of the first region and a plurality of second patterns which are spaced apart from one another in the middle light exposure region of the second region by removing the double tone photoresist layer in the low light exposure region of the plurality of preliminary patterns of the first region and the double tone photoresist layer in the low light exposure region of the second region by performing a negative development process.

12. The method of claim 11, wherein the gray feature comprises a sub-resolution feature which is formed in the plurality of mask patterns in the second mask region or between the plurality of mask patterns in the second mask region.

13. The method of claim 12, wherein widths of the plurality of first patterns are a width of the middle light exposure region of the first region.

14. The method of claim 12, wherein widths of the plurality of second patterns are a width of the middle light exposure region of the second region.

15. The method of claim 12, wherein a width of the middle light exposure region of the second region is greater than a width of the middle light exposure region of the first region.

16. A method of forming a pattern, the method comprising:
forming a dual tone photoresist layer on a support layer;
exposing the dual tone photoresist layer to light by using a mask comprising a gray feature;
removing the dual tone photoresist layer in a first portion of a first region by performing a positive development process; and
removing the dual tone photoresist layer in a second portion of the first region and removing the dual tone photoresist layer in a first portion of a second region by performing a negative development process.

17. The method of claim 16, wherein the first portion of the first region comprises a high light exposure region, and the second portion of the first region comprises a low light exposure region.

18. The method of claim 16, wherein the first portion of the second region comprises a low right exposure region.

19. The method of claim 16, wherein the gray feature comprises a sub-resolution feature which is formed in a plurality of mask patterns in a second mask region or between the plurality of mask patterns in the second mask region.

20. The method of claim 16, further comprising performing a soft bake process after forming the dual tone photoresist layer.
